(19) United States
(12) Patent Application Publication
(10) Pub. No.: US 2026/0152852 A1
(43) Pub. Date: Jun. 4, 2026

(54) CUPPED BAFFLE PLATES FOR SHOWERHEADS OF SUBSTRATE PROCESSING SYSTEMS

(71) Applicant: LAM RESEARCH CORPORATION, Fremont, CA (US)

(72) Inventors: Andrew BORTH, Newberg, OR (US); Conor Charles ARCURI, Beaverton, OR (US)

(21) Appl. No.: 19/122,393

(22) PCT Filed: Oct. 18, 2023
(86) PCT No.: PCT/US2023/035376

§ 371 Date: Apr. 18, 2025

(51) Int. Cl. C23C 16/455; C23C 16/46; C23C 16/52

(52) U.S. Cl. CPC C23C 16/45565; C23C 16/46; C23C 16/52

(57) ABSTRACT

A cupped baffle plate for a showerhead of a substrate processing system includes: a baseplate to be disposed in a plenum of the showerhead to receive a fluid from a stem of the showerhead, the baseplate includes holes to receive standoff elements for coupling the baseplate to at least one of a backplate or a faceplate of the showerhead; and a circumferential lip on the baseplate and adjacent to an outer peripheral edge of the baseplate. The circumferential lip restricts fluid flow over a peripheral edge of the cupped baffle plate. WO

### CROSS-REFERENCE TO RELATED APPLICATIONS

This application claims the benefit of U.S. Provisional Application No. 63/419,124, filed on Oct. 25, 2022. The entire disclosure of the above application is incorporated herein by reference.

### FIELD

The present disclosure relates to baffle plates of showerhead assemblies in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to perform treatments such as deposition and etching of film on substrates such as semiconductor wafers. For example, deposition may be performed to deposit conductive film, dielectric film, or other types of film using chemical vapor deposition (CVD), plasma enhanced CVD (PECVD), atomic layer deposition (ALD), plasma enhance ALD (PEALD), and/or other deposition processes. During deposition, the substrate is arranged on a substrate support (e.g., a pedestal) and one or more precursor gases may be supplied to a processing chamber using a gas distribution device (e.g., a showerhead) during one or more process steps. In a PECVD or PEALD process, plasma is used to activate chemical reactions within the processing chamber during deposition.

### SUMMARY

A cupped baffle plate for a showerhead of a substrate processing system is disclosed. The cupped baffle plate includes: a baseplate to be disposed in a plenum of the showerhead to receive a fluid from a stem of the showerhead, the baseplate includes holes to receive standoff elements for coupling the baseplate to at least one of a backplate or a faceplate of the showerhead; and a circumferential lip on the baseplate and adjacent to an outer peripheral edge of the baseplate. The circumferential lip restricts fluid flow over a peripheral edge of the cupped baffle plate.

In other features, the circumferential lip has a rectangular-shaped cross-section. In other features, the circumferential lip includes a ramped surface. In other features, the circumferential lip includes a rounded upper surface. In other features, the circumferential lip includes: a first circumferential edge with a rounded cross-section; and a second circumferential edge with a cross-section having a right angle.

In other features, the circumferential lip has a stepped surface. In other features, the circumferential lip includes ramped surfaces. In other features, the circumferential lip includes a ramped surface and a flat top surface.

In other features, a width of a cross-section of the circumferential lip is less than a height of the circumferential lip. In other features, the cupped baffle plate includes a post hole to receive a temperature measuring device post. In other features, the circumferential lip extends upward from the baseplate and is integrally formed with the baseplate as a unitary component.

In other features, a showerhead is disclosed and includes: the cupped baffle plate; the backplate including a fluid supply hole; the faceplate attached to the backplate, the faceplate in combination with the backplate defining the plenum; and the stem including a fluid channel supplying the fluid to the plenum via the fluid supply hole. An exit area of the cupped baffle plate is greater than a cross-sectional area of at least one of the fluid supply hole and the fluid channel, the exit area is cylindrical shaped and is equal to a product of i) a distance between the circumferential lip and the backplate, and ii) at least one of an outer circumference of the cupped baffle plate and an uppermost circumferential edge of the circumferential lip.

In other features, a height of the circumferential lip is less than a distance between the backplate and the baseplate. In other features, the showerhead further includes a temperature measuring device post to receive a temperature measuring device, the temperature measuring device post extends through a hole in the cupped baffle plate.

In other features, the temperature measuring device post extends from the faceplate and to the backplate. In other features, the standoff elements extend from at least one of the backplate and the faceplate. In other features, the standoff elements extend from the backplate and not from the faceplate. In other features, the exit area of the cupped baffle plate is at least four times the cross-sectional area of the at least one of the fluid supply hole and the fluid channel.

In other features, a cupped baffle plate for a showerhead of a substrate processing system is disclosed. The cupped baffle plate includes a baseplate and a circumferential lip. The baseplate is disposed in a plenum of the showerhead and receives a fluid from a stem of the showerhead. The baseplate includes: holes to receive standoff elements for coupling the baseplate to a backplate of the showerhead; and a post hole to receive a temperature measuring device post. The circumferential lip is on the baseplate and adjacent to an out peripheral edge of the baseplate. The circumferential lip in combination with the baseplate reduces turbulence in fluid flow radially outward of the holes and the post hole and over a peripheral edge of the cupped baffle plate.

In other features, a showerhead is disclosed and includes: the cupped baffle plate; the backplate including a fluid supply hole; a faceplate attached to the backplate, the faceplate in combination with the backplate defining the plenum; and the stem including a fluid channel supplying the fluids to the plenum via the fluid supply hole. An exit area of the cupped baffle plate is greater than a cross-sectional area of at least one of the fluid supply hole and the fluid channel, the exit area is cylindrical shaped and is equal to a product of i) a distance between the circumferential lip and the backplate, and ii) at least one of an outer circumference of the cupped baffle plate and an uppermost circumferential edge of the circumferential lip.

In other features, a width of a cross-section of the circumferential lip is less than a height of the circumferential lip. A height of the circumferential lip is less than a distance between the backplate and the baseplate. In other features, the exit area of the cupped baffle plate is at least four times the cross-sectional area of the at least one of the fluid supply hole and the fluid channel.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is an example fluid flow velocity diagram illustrating fluid flow velocities of fluid above a substrate and from a showerhead that does not have a temperature measuring device (TMD) post;

FIG. 2 is an example fluid flow velocity diagram illustrating fluid flow velocities above a substrate and from a showerhead that has a TMD post;

FIG. 3 is a functional block diagram of a substrate processing system including a showerhead with a cupped baffle plate in accordance with the present disclosure;

FIG. 4 is an example controller and showerhead in accordance with the present disclosure;

FIG. 5 is a perspective view of a showerhead in accordance with the present disclosure;

FIG. 6 is a cross-sectional view of a portion of the showerhead of FIG. 5 illustrating a cupped baffle plate and a temperature measuring device post in accordance with the present disclosure;

FIG. 7 is a cross-sectional view of another portion of the showerhead of FIG. 5 illustrating dimensions of the cupped baffle plate relative to a backplate;

FIG. 8 is a fluid flow diagram illustrating flow of fluid onto a cupped baffle plate and across and over a circumferential lip of the cupped baffle plate in accordance with the present disclosure;

FIG. 9 is a fluid flow velocity diagram illustrating fluid flow velocities above a substrate and from a showerhead that has a cupped baffle plate and a TMD post in accordance with the present disclosure;

FIG. 10 is a side cross-sectional view of a portion of a cupped baffle plate including a circumferential lip having a triangular-shaped cross-section in accordance with the present disclosure;

FIG. 11 is a side cross-sectional view of a portion of a cupped baffle plate including a circumferential lip having a hemi-spherically-shaped cross-section in accordance with the present disclosure;

FIG. 12 is a side cross-sectional view of a portion of a cupped baffle plate including a circumferential lip having a rounded inner circumferential edge and a right angled outer circumferential edge in accordance with the present disclosure;

FIG. 13 is a side cross-sectional view of a portion of a cupped baffle plate including a circumferential lip with a right angled inner circumferential edge and a rounded outer circumferential edge in accordance with the present disclosure;

FIG. 14 is a side cross-sectional view of a portion of a cupped baffle plate including circumferential lip having a ramped cross-section in accordance with the present disclosure;

FIG. 15 is a side cross-sectional view of a portion of a cupped baffle plate including circumferential lip having a ramped cross-section with a flat top portion in accordance with the present disclosure;

FIG. 16 is a side cross-sectional view of a portion of a cupped baffle plate including circumferential lip having a right angled inner circumferential edge and downward sloped outer circumferential surface in accordance with the present disclosure;

FIG. 17 is a side cross-sectional view of a portion of a cupped baffle plate including a circumferential lip with a stepped inclining cross-section in accordance with the present disclosure; and

FIG. 18 illustrates a method of operating a substrate processing system including a cupped baffle plate in accordance with the present disclosure.

In the drawings, reference numbers may be reused to identify similar and/or identical elements.

### DETAILED DESCRIPTION

A processing chamber of a substrate processing system typically includes a showerhead, which is used to deliver gas mixtures, and can be used as an electrical power conductor. A showerhead can include a stem with an internal channel through which gases and precursors are supplied. The gases and precursors are received at a first end of the stem and provided to a showerhead at a second end of the stem. The showerhead can include a baffle plate, which is used to restrict, distribute and/or mix the gases and precursors within the showerhead. The electrical power applied to the showerhead can be used to generate plasma between the showerhead and the substrate support, or for other aspects of the substrate processing system that require electrical power.

A showerhead, in addition to including a baffle plate, can also include corresponding support posts (or “standoff elements”), which hold the baffle plate in a plenum between a backplate and a faceplate. The standoff elements may be connected to the backplate and/or the faceplate. The baffle plate is suspended in the plenum and below an outlet of a stem and receives fluids (gases and/or liquids) flowing through the stem. The fluids flow over and/or through the baffle plate to the faceplate, which is perforated. The baffle plate may be non-perforated (i.e., have no holes) or perforated (i.e., have one or more holes).

The showerhead may also include a temperature measuring device (TMD), which may be disposed in a post (referred to as a “TMD post”) extending through the baffle and between the backplate and faceplate. The TMD may be used to detect and adjust temperatures within the showerhead. Processing operations may also be adjusted based on the temperature detected by the TMD.

Standoff elements that are connected to the backplate and extend from the backplate to the baffle plate can cause low pressure wakes in the flow of fluids across and over the baffle plate. A TMD post that extends from the backplate and through the baffle plate also can cause a low-pressure wake in the flow of fluids across and over the baffle plate.

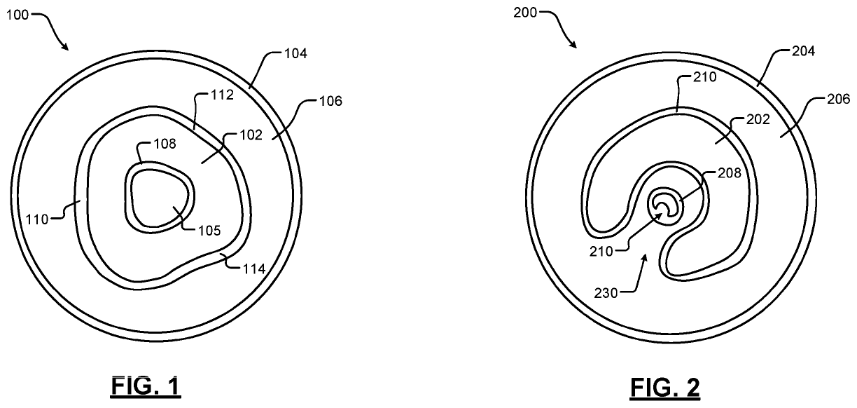

Referring to FIGS. 1-2, fluid flow velocity diagrams associated with respective showerheads having respective baffle plates are shown. The fluid flow velocities may be estimated for example at an area 1 mm above substrates being processed. FIG. 1 shows an example fluid flow velocity diagram 100 for axial (or vertical) fluid flow velocities from a showerhead not having a TMD post. In FIG. 1, fluid flow velocities experienced by a substrate are shown, where different regions experiencing different velocities are outlined. Region 102 experiences the highest fluid flow velocities and is associated with fluid flow over a circumferential edge of the baffle plate. Region 104 experiences the lowest fluid flow velocities. Regions 105, 106 experience fluid flow velocities higher than the fluid flow velocities experienced in region 104. Regions 108, 110, 112, 114 experience fluid flow velocities, which are lower than the fluid flow velocities in region 102 and higher than the fluid flow velocities in regions 105, 106.

Since there is not a TMD post in the showerhead, fluid flow velocities below the baffle plate, as shown in region 105, are within a same fluid flow velocity range. For example, each fluid flow velocity experienced in region 105 is less than or equal to 0.001 meters per second m/s different than other fluid flow velocities experienced in region 105.

FIG. 2 shows an example fluid flow velocity diagram 200 for axial fluid flow velocities from a showerhead having a TMD post. In FIG. 2, fluid flow velocities experienced by a substrate are shown, where different regions experiencing different velocities are outlined. Region 202 experiences the highest fluid flow velocities. Region 202 is associated with fluid flow over a circumferential edge of the baffle plate. Region 204 experiences the lowest fluid flow velocities. Region 206 experiences fluid flow velocities higher than the fluid flow velocities experienced in region 204. Regions 208, 210 experience fluid flow velocities, which are lower than the fluid flow velocities in region 202 and higher than the fluid flow velocities in regions 206.

Since there is a TMD post in the showerhead, fluid flow velocities below and near the TMD post, represented by area 210 are lower than in region 206. In addition, fluid flow velocities in area 230 are lower than fluid flow velocities in regions 202, 210 due to the low-pressure wake created by the TMD post above the baffle plate.

The low fluid flow velocity areas 210 and 230 of FIG. 2 can cause non-uniformities in deposition on a substrate being processed. This non-uniformity can be experienced across a substrate and cause repeatability issues from substrate-to-substrate.

The examples set forth herein include showerhead assemblies including cupped baffle plates and TMD posts. Each of the cupped baffle plates has a peripheral annular-shaped portion (referred to as the “lip”) that protrudes upward from a base portion (referred to as the “baseplate”). The lip provides a restriction radially outside of the TMD post and improves uniformity of velocities of fluid flowing over the lip of the cupped baffle plate. The restriction does not have a negative effect on overall fluid flow, but rather simply smooths out and provides uniform fluid flow over a circumferential lip of the cupped baffle plate. Fluid received from a stem pools in the cupped baffle plate, which results in improved fluid pressure and flow rate uniformity prior to, on and over the circumferential lip. The TMD posts disclosed herein are also sized to minimize effect on fluid flow while maintaining structural integrity of the TMD posts.

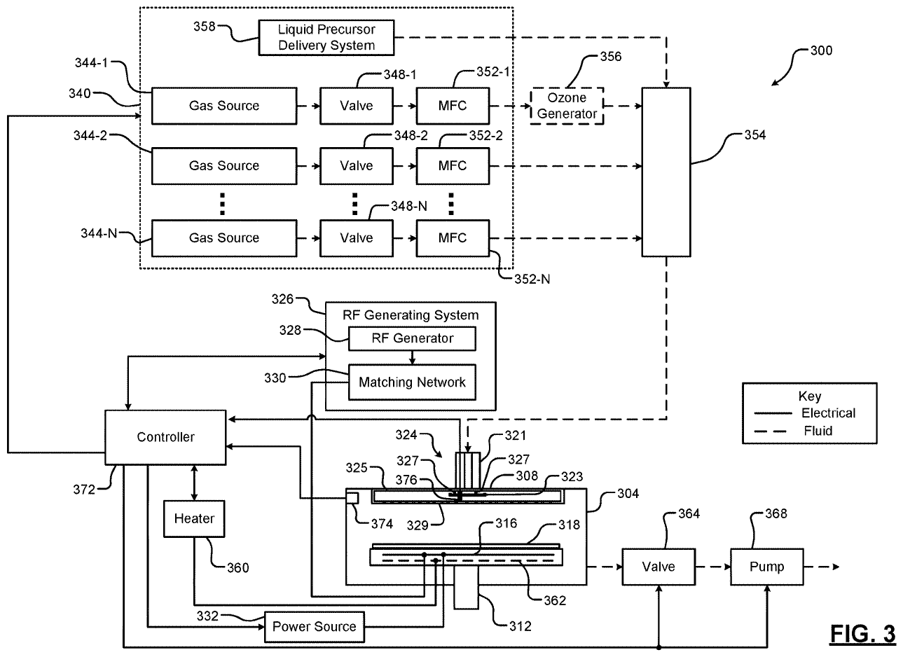

FIG. 3 shows a substrate processing system 300 including a showerhead with a cupped baffle plate. The example of FIG. 3 is applicable to PECVD chambers and other plasma-based substrate processing chambers. The substrate processing system 300 includes a processing chamber 304 that encloses other components of the substrate processing system 300. The substrate processing system 300 comprises a first electrode 308 and a substrate support such as a pedestal 312 including a second electrode 316. For example, the first electrode 308 may be an upper electrode. The second electrode 316 may be a lower electrode. A substrate 318 is arranged on the pedestal 312 between the first electrode 308 and the second electrode 316 during processing.

For example only, the first electrode 308 may include a showerhead 324 that introduces and distributes process gases. In some examples, the showerhead 324 may not be configured for active temperature control. For example, the showerhead 324 is not configured to be actively heated and/or cooled (e.g., using resistive heaters, coolant flowed through coolant channels, etc.). In other words, the showerhead 324 does not comprise active heating components (e.g., embedded resistive heaters) and/or does not comprise active cooling components (e.g., channels configure to flow coolant throughout the showerhead 324).

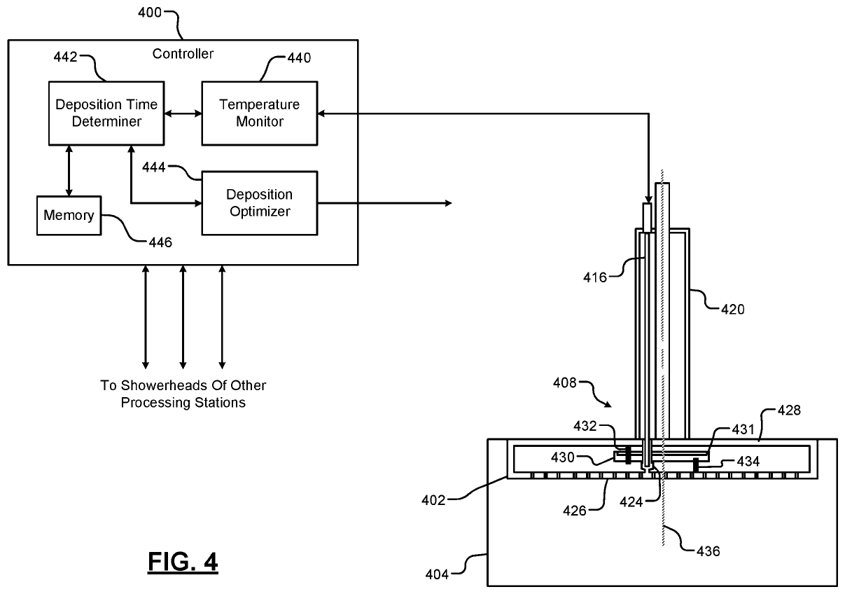

The showerhead 324 includes a stem 321 that receives processing fluids and directs the processing fluids towards a cupped baffle plate 323. The cupped baffle plate 323 may be configured as any of the cupped baffle plates disclosed herein. Other examples of cupped baffle plates are shown in FIGS. 4, 6 and 10-17. The cupped baffle plate 323 may have various dimensions, sizes, and shapes. The cupped baffle plate 323 may be at various distances from a backplate 325. The cupped baffle plate 323 may be held by standoff elements 327 that are connected to the backplate 325, as shown, or to a faceplate 329.

The second electrode 316 may correspond to a conductive electrode embedded within a non-conductive portion of the pedestal 312. Alternately, the pedestal 312 may comprise an electrostatic chuck that comprises a conductive plate that acts as the second electrode 316.

A radio frequency (RF) generating system 326 generates and outputs an RF voltage to the first electrode 308 and/or the second electrode 316 when plasma is used. In some examples, one of the first electrode 308 and the second electrode 316 may be DC grounded, AC grounded, or at a floating potential. For example only, the RF generating system 326 may comprise one or more RF voltage generators 328 (e.g., a capacitively-coupled plasma RF power generator, a bias RF power generator, and/or other RF power generator) such as an RF voltage generator 328 that generate RF voltages. The RF voltages are fed by one or more matching and distribution networks 330 to the second electrode 316 and/or the first electrode 308. For example, as shown, the RF voltage generator 328 provides an RF and/or bias voltage to the second electrode 316. The second electrode 316 may receive power alternatively or additionally from other power sources, such as a power source 332. In other examples, an RF voltage may be supplied to the first electrode 308 or the first electrode 308 may be connected to a ground reference.

An example gas delivery system 340 comprises one or more gas sources 344-1, 344-2, . . . , and 344-N (collectively gas sources 344), where N is an integer greater than zero. The gas sources 344 supply one or more gases (e.g., precursors, inert gases, etc.) and mixtures thereof. Vaporized precursor may also be used. At least one of the gas sources 344 may contain gases used in the pre-treatment process of the present disclosure (e.g., NH₃, N₂, etc.). The gas sources 344 are connected by valves 348-1, 348-2, . . . , and 348-N (collectively valves 348) and mass flow controllers 352-1, 352-2, . . . , and 352-N (collectively mass flow controllers 352) to a manifold 354. An output of the manifold 354 is fed to the processing chamber 304. For example only, the output of the manifold 354 is fed to the showerhead 324.

In some examples, an optional ozone generator 356 may be provided between the mass flow controllers 352 and the manifold 354. In some examples, the substrate processing system 300 may comprise a liquid precursor delivery system 358. The liquid precursor delivery system 358 may be incorporated within the gas delivery system 340 as shown or may be external to the gas delivery system 340. The liquid precursor delivery system 358 is configured to provide precursors that are liquid and/or solid at room temperature via a bubbler, direct liquid injection, vapor draw, etc.

A heater 360 may be connected to a heater coil 362 arranged in the pedestal 312 to heat the pedestal 312. The heater 360 may be used to control a temperature of the pedestal 312 and the substrate.

A valve 364 and pump 368 may be used to evacuate reactants from the processing chamber 304. A controller 372 may be used to control various components of the substrate processing system 300. For example only, the controller 372 may be used to control flow of process, carrier, and precursor gases, striking and extinguishing plasma, removal of reactants, monitoring of chamber parameters, etc. The controller 372 may receive measurement signals indicative of process parameters, conditions within the processing chamber 304, etc. via one or more sensors 374 arranged throughout the substrate processing system 300.

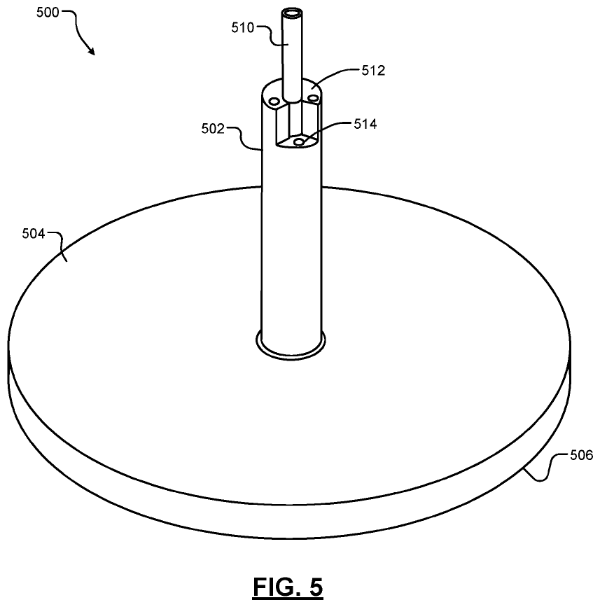

The controller 372 according to the present disclosure is further configured to monitor a temperature of the showerhead 324. The controller 372 is further configured to adjust process time (e.g., deposition time, period, or duration) to compensate for variations in the showerhead temperature. For example, a TMD (not shown in FIG. 1) disposed in a TMD post 376, which is located within the showerhead 324, is configured to monitor a temperature of the showerhead 324 during deposition. Examples of the TMD post are shown in FIGS. 6-7. The TMD may be implemented as a thermocouple or other temperature measurement device. In one embodiment, the TMD includes a fiber optic line encased in a sheath that extends through the stem to a probe, which may be a ceramic phosphor tip. The sheath may be formed of stainless-steel. This provides a rigid structure that is able to be feed through the stem 321 and into the TMD post 376. The TMD, in this implementation, is able to be easily accessed and serviced from a top portion of the stem 321. In another embodiment, the TMD includes a flexible wire that is fed through the stem 321 and into the TMD post 376. The flexible wire may have a temperature sensing element at an end of the wire that is disposed into the TMD post 376.

The controller 372 receives a signal from the TMD indicating the showerhead temperature. The controller 372 is configured to selectively (e.g., periodically or continuously) determine and update deposition time based on the monitored temperature of the showerhead 324 as described below in more detail. The controller 372 may also adjust other parameters based on the temperature, such as fluid flow rates, temperature of the pedestal 312, power to the second electrode 316, etc.

While described below with respect to a single processing chamber 304 and pedestal 312, the principles of the present disclosure may be implemented in systems comprising multiple processing chambers and processing chambers comprising multiple processing stations and pedestals, such as a quad station module (QSM). For example, each showerhead in a corresponding processing station of a QSM may implement one or more sensors for monitoring temperature and adjusting deposition accordingly. In other words, deposition times at each processing station can be independently adjusted to compensate for temperatures of respective ones of the showerheads.

FIG. 4 shows a controller 400 and a showerhead 402 with a stem 420 (collectively shown at 408) in a processing chamber 404. The controller 400 may replace the controller 372 of FIG. 3. The controller 400 is configured to monitor a temperature of the showerhead 402. The showerhead 402 may not be configured for active temperature adjustment. For example, the showerhead 402 may not comprise a heater (e.g., a resistive heater). The controller 400 may adjust length a deposition time period to compensate for variations in the showerhead temperature. The showerhead 402 is arranged to provide process gases to the processing chamber 404.

The showerhead 402 and the processing chamber 404 may correspond to a single processing station in a multi-station processing tool (e.g., a quad station module). The controller 400 may be configured to monitor temperatures of multiple showerheads of respective processing stations, independently adjust deposition times and/or other parameters in each of the processing stations, etc. The controller 400 may adjust deposition times and/or other parameters in a plurality of stations based on monitored temperatures of only one of the showerheads (e.g., the showerhead 402).

In this example, a TMD 416 is routed through the stem 420 into a TMD post 424 of the showerhead 402. For example, an end of the TMD 416 is located near a faceplate 426 of the showerhead 402. In an embodiment, the TMD post 424 may be integrally formed with the faceplate 426 as a single component. In an embodiment, the stem 420, a backplate 428, a cupped baffle plate 430, and the faceplate 426 are formed of the same material. As an example, the stem 420, the backplate 428, the cupped baffle plate 430, and the faceplate 426 may be formed of aluminum. The cupped baffle plate 430 may be held by standoff elements 432, 434. Although only two standoff elements are shown in FIG. 4, three or more standoff elements may be used. As an example, the standoff elements may be disposed 120° apart from each other relative to a longitudinal centerline 436 extending through a center of the stem 420 and the showerhead 402. The standoff elements may be connected to the backplate 428 and/or the faceplate 426. In one embodiment, the standoff elements are connected to the backplate 428 and not to the faceplate 426. In another embodiment, the standoff elements are connected to the faceplate 426 and not to the backplate 428.

The controller 400 may include a temperature monitor 440, a deposition time determiner 442, and a deposition optimizer 444. The temperature monitor 440 receives and processes a signal from the TMD 416 indicating the temperature of the showerhead 402. For example, the temperature monitor 440 may convert an analog signal to a digital signal that is indicative of the temperature. The temperature monitor 440 outputs a signal indicating the sensed showerhead temperature to the deposition time determiner 442.

The deposition time determiner 442 is configured to determine a deposition time for a deposition step based on the sensed showerhead temperature. Deposition thickness may be directly correlated (e.g., linearly correlated) to showerhead temperature. For example, as showerhead temperature increases, deposition thickness for a fixed deposition duration may also increase. Conversely, as showerhead temperature decreases, deposition thickness for the same fixed deposition duration also decreases. In some examples, deposition thickness may decrease as showerhead temperature increases and increase as showerhead temperature decreases. The deposition time determiner 442 determines and selectively adjusts the deposition time to compensate for variations in showerhead temperature and achieve a desired deposition thickness.

In one example, the deposition time determiner 442 receives the showerhead temperature and determines the deposition time prior to beginning a deposition step or process. For example, the deposition time determiner 442 determines the deposition time for a next substrate subsequent to performing deposition on a previous substrate (i.e., between deposition steps performed on successive substrates in a sequence). The deposition time determiner 442 determines the deposition time based on the showerhead temperature and a desired deposition thickness. Alternatively, the deposition time determiner 442 determines an adjustment or offset to a baseline or default deposition time (e.g., a deposition time adjustment percentage, time offset, etc.). The deposition time determiner 442 provides deposition time information (e.g., the determined deposition time, a deposition time adjustment, etc.) to the deposition optimizer 444. The deposition optimizer 444 controls the deposition step for a deposition duration based on the deposition information, such as controlling operation of the gas delivery system 340, the RF generating system 326, the heater 360, the power source 332, etc. of FIG. 3.

In another example, the deposition time determiner 442 continues to determine the deposition time based on showerhead temperatures sensed and received during the deposition step. In other words, instead of determining the deposition time only once prior to beginning the deposition step and performing the deposition step for the determined deposition time, the deposition time determiner 442 may make further adjustments to the deposition time based on temperature variation during the deposition step (i.e., in real-time as a deposition step is being performed).

The deposition time determiner 442 determines the deposition time based on data that correlates showerhead temperature to a deposition rate, a deposition thickness for a baseline deposition time, etc. For example, the data corresponds to showerhead temperature compensation data stored in memory 446. In one example, the stored data may comprise a lookup table that correlates showerhead temperature to deposition rate, deposition thickness, a deposition time for a desired deposition thickness, etc. In another example, the stored data is a model or formula configured to determine a deposition time based on one or more inputs comprising, but not limited to, the showerhead temperature as measured prior to the deposition step and a default or baseline deposition time.

The cupped baffle plate 430 and the controller 400 are configured to improve deposition uniformity across a substrate. The cupped baffle plate 430 exhibits uniform fluid flow over a circumferential lip 431, which provides improved uniformity in fluid flow pressures across the substrate for improved deposition uniformity. The controller 400 may also control the showerhead temperature to improve deposition uniformity. In substrate processing systems, process uniformity may vary based on a temperature of a gas distribution device (e.g., a showerhead configured to flow process gases, plasma, etc. into a processing chamber). The controller 400 adjusts deposition parameters such as process time (e.g., a deposition, time, period or duration) to compensate for variations in showerhead temperature without continuously adjusting the showerhead temperature. In other words, instead of adjusting the showerhead temperature (e.g., the system is not configured to actively adjust showerhead temperature using controllable heater, such as a resistive heater), the deposition time may be increased or decreased to compensate for changes in deposition rates caused by variations in the showerhead temperature. For example, stored data may correlate showerhead temperature to deposition time, deposition thickness for a baseline deposition time, a deposition rate, etc. As used herein, the baseline deposition time corresponds to a default deposition time for a desired deposition thickness. Accordingly, as variations in showerhead temperature are monitored prior to and/or during a deposition step, the deposition time may be automatically adjusted based on the variations in showerhead temperature.

FIG. 5 shows an example showerhead 500 that includes a stem 502, a backplate 504, and a faceplate 506. The stem 502 includes a fluid inlet pipe 510, an outer cylindrical-shaped housing (or pipe) 512, and a TMD access channel 514. Any of the TMDs referred to herein may be disposed in a TMD post (not shown in FIG. 5) that is located between the plates 504, 506 and is horizontally inline with the TMD access channel 514. As an example, a TMD may slide down the TMD access channel 514 and may be inserted in the TMD post. Similarly, the TMD may be removed from the TMD post by pulling the TMD out of the TMD access channel 514.

FIG. 6 shows a portion 600 of the showerhead 500 of FIG. 5 illustrating a cupped baffle plate 602 and a TMD post 604. The showerhead 500 includes the stem 502 having the fluid inlet pipe 510 with a fluid channel 610 and an outer cylindrically-shaped housing 612 with a TMD access channel 614 for a TMD 616. The cupped baffle plate 602 is held in a plenum 620 by standoff elements 622. As a couple of examples, the cupped baffle plate 602 may be welded to the standoff elements 622 or held on the standoff elements 622 via fasteners (e.g., screws). In one embodiment, the cupped baffle plate 602 is welded to the TMD post 604 and welded and/or fastened to the standoff elements 622. The fasteners may be screwed into the standoff elements 622. The standoff elements 622 may be integrally formed as part of a backplate 504 of the showerhead or attached to (e.g., welded to) the backplate 504. The cupped baffle plate 602 may have holes 623 through which portions of the standoff elements extend.

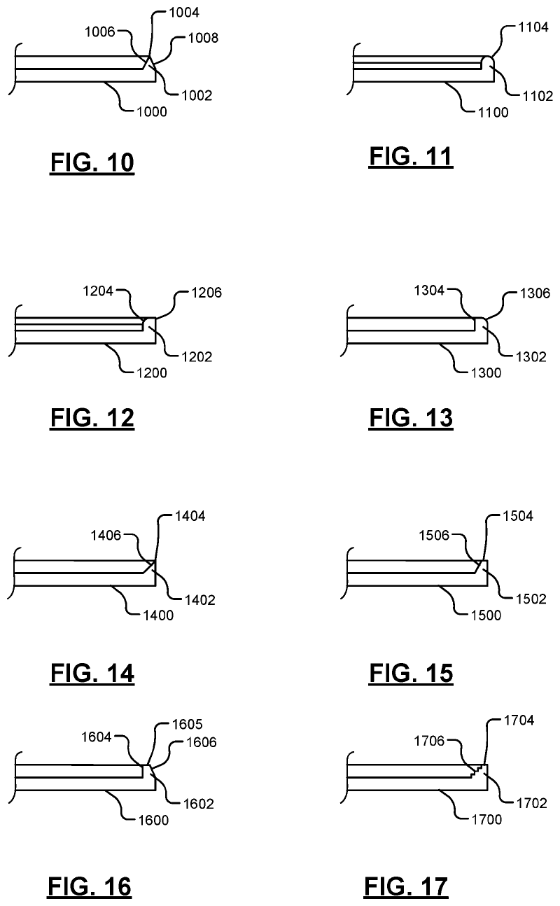

The cupped baffle plate 602 includes a baseplate 630 and a circumferential lip 632 that extends upward from the baseplate 630. The lip 632 is located on and/or integrally formed as part of the baseplate 630. The lip 632 is located adjacent to a peripheral outer edge 633 of the baseplate 630. The lip 632 is shown having a rectangular cross-sectional shape, but may have other cross-sectional shapes as shown, for example, in FIGS. 10-17. The lip 632 in combination with the baseplate 630 provides a pooling area 634 for fluid received from the fluid channel 610 via a hole 635 in a backplate 504 of the showerhead. The hole 635 is aligned horizontally with the fluid channel 610. The fluid channel 610 has an inner diameter ID1.

The TMD post 604 may be integrally formed as part of the faceplate 506, as shown or be attached to the faceplate 506. The TMD post 604 includes a first cylindrical portion 650 and a second cylindrical portion 652 that has a smaller outer diameter than the first cylindrical portion 650, example diameters of which are shown in FIG. 7. The second cylindrical portion 652 extends through a hole 654 in the cupped baffle plate 602 and through a post hole 655 in the backplate 504 up to the stem 502. The first cylindrical portion 650 and the second cylindrical portion 652 have respective inner channels 658, 660. The inner channels 658, 660 are horizontally aligned to allow insertion and removal of the TMD 616. The TMD 616 may be a thermocouple or other temperature measuring device. As an example, the TMD may include a sheathed optical fiber that extends to a temperature sensing element 662, such as a ceramic phosphor tip.

The faceplate 506 of the showerhead 500 may include any pattern of holes 670 for outputting fluids from the plenum 620 down towards a substrate being processed. The holes 670 may have various inner diameters. The TMD post 604 is disposed between the holes 670. A bottom end 672 of the TMD post 604 may be narrowed to have a smaller diameter than a diameter of the first cylindrical portion 650. This allows for placement of the TMD post 604 between ones of the holes 670 that are close to each other. The stem 502, backplate 504, faceplate 506, cupped baffle plate 602, TMD post 604, and standoff elements 622 may be formed of the same material (e.g., aluminum).

FIG. 7 shows another portion 700 of the showerhead 500 illustrating dimensions of the cupped baffle plate 602 relative to the backplate 504. In FIG. 7, the cupped baffle plate 602 including the baseplate 630 and lip 632, the standoff elements 622, and the TMD post 604 including the portions 650, 652 and the bottom end 672 are shown. The backplate 504 has the holes 635 and 655.

The cupped baffle plate 602 has a baffle height BH, a lip height LH, a lip width LW, an outer diameter OD1, and an inner lip diameter ID2. A first gap G1 exists between the baseplate 630 and the backplate 504. A second gap G2 exists between the lip 632 and the backplate 504. The lip heigh LH is equal to a depth of the fluid pooling area 634 of the cupped baffle plate 602 and is less than the gap G1. The gap G1 is greater than the gap G2. As an example, the gap G1 may be 0.10 inches (in) to 0.50 in (or 2.54 millimeters (mm) to 12.70 mm). The lip width LW may be less than the lip height LH. As an example, the lip height LH may be 0.020-0.40 in (or 0.51-10 mm). As an example, the lip width LW may be 0.02-0.12 in (or 0.51-3.05 mm). As an example, the outer diameter OD1 may be 1.50-3.25 in (or 38.10-82.60 mm).

The first cylindrical portion 650 of the TMD post 604 has an outer diameter OD2 and a wall thickness WT1. The second cylindrical portion 652 has an outer diameter OD3 and a wall thickness WT2. The outer diameter OD2 may be larger than the outer diameter OD3, such that the TMD post is locked in the cupped baffle plate 602 and the backplate 504 and between the cupped baffle plate 602 and the faceplate 506. The wall thickness WT2 may be less than or equal to the wall thickness WT1. As an example, each of the outer diameters OD2, OD3 may be 0.19-0.38 in (or 4.83-9.65 mm). Although the ranges of OD2-OD3 may be the same, OD3 is smaller than OD2. As an example, the wall thicknesses WT1, WT2 may each be 0.03-0.12 in (or 0.76-3.05 mm). Although the ranges of WT1, WT2 may be the same, WT2 is smaller than WT1. As an example, outer diameters of the standoff elements 622 may be 0.18-0.40 in (or 4.57-10.16 mm). The outer diameters OD2, OD3, OD4 and wall thicknesses WT1, WT2 are minimized while maintaining structural integrity of the TMD post 604. This minimizes effect of the TMD post on fluid flow velocities.

In one embodiment, the lip height LH is less than the gap G2. In another embodiment, the lip heigh LH is greater than or equal to the gap G2. In an embodiment, the gap G2 is less than the baseplate height BH. In one embodiment, the lip width LW is less than the lip height LH. In another embodiment, the lip width is greater than or equal to the lip height LH. In an embodiment, the gaps G1 and G2 are less than a distance between the cupped baffle plate 602 and the faceplate 506.

Upper and lower portions of an outer peripheral side 640 of the cupped baffle plate 602 are outer peripheral sides respectively of the lip 632 and the baseplate 630. The lip 632 is on and extends upward from the baseplate 630, is adjacent to the outer peripheral side (or edge) of the baseplate 630, and may be integrally formed with the baseplate 630 to provide a unitary component.

The lip 632 does not overly restrict fluid flow. An area of cupped baffle plate exit (referred to as the exit area) may be greater than at least one of i) a cross-sectional area of the hole 635, and ii) a cross-sectional area of the fluid channel 610 of FIG. 6. The exit area refers to a cylindrically-shaped area between the lip 632 and the backplate 504. The exit area is equal to a product of i) the gap G2 (or distance between the lip 632 and the backplate 504, and ii) an outer circumference of the cupped baffle plate 602 and/or outer and uppermost circumferential edge of the lip 632. As an example, the exit area may be 0.42 in² and the cross-sectional area of the hole 635 may be 0.10 in² . The hole 635 has an inner diameter ID3, which may be the same as the inner diameter ID1 of the fluid channel 610 of FIG. 6. As an example, ID1 and ID3 may each be 0.25-0.50 in (or 6.35-12.70 mm). In an example embodiment, the exit area is four or more times at least one of i) the cross-sectional area of the hole 635, and ii) the cross-sectional area of the fluid channel 610.

The lip 632 performs as a weir and adds restriction to fluid flow downstream of the TMD post 604 and the standoff elements 622. The fluid may be turbulent as it is ejected out of the hole 635 and upstream of the TMD post 604 and the standoff elements 622 and coalesces in the cupped baffle plate 602 and smoothly flow over the lip 632. The lip 632 and the baseplate 630 reduce turbulence in fluid flow over the cupped baffle plate 602, which results in more uniform fluid flow velocities over a peripheral edge of the cupped baffle plate 602. This is illustrated in FIG. 8.

FIG. 8 shows a fluid flow diagram illustrating flow of fluid onto a cupped baffle plate 802 and over a circumferential lip 800 of the cupped baffle plate 802. Fluid flows from a stem and through a hole in a backplate toward a central area 804 of the cupped baffle plate 802. The fluid is then radially dispersed across the cupped baffle plate 802, as shown by radially extending arrows 806. The fluid flow rates smooth out from the central area 804 to an inner circular area 810 that is adjacent to and radially inward of the lip 800. The fluid may be turbulent (i.e., having different fluid flow velocities), near the central area 804 and become less turbulent through the intermediate area 812. A reduction in fluid flow may exist between a TMD post 820 and one of the standoff elements 822, as represented by area 824. Velocities of fluid flow over the lip 800 may be the same or similar. For example, the velocities may be within 0.0002-0.0006 meters per second (m/s) of each other.

There is not a significant reduction in fluid velocity in the wake of a TMD post and/or standoff element. There are some velocity differences exhibited in zones correlating to TMD post and standoff elements, but these differences phase out by the time the fluid reaches the lip 632.

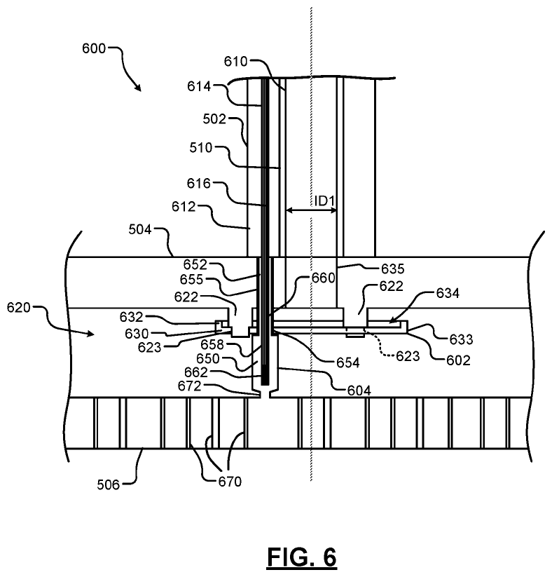

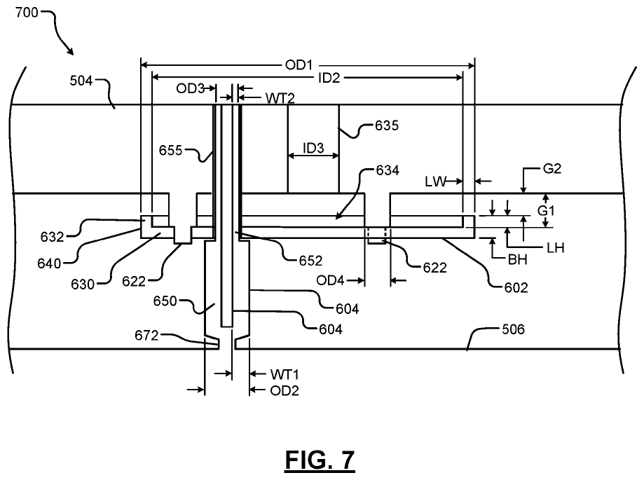

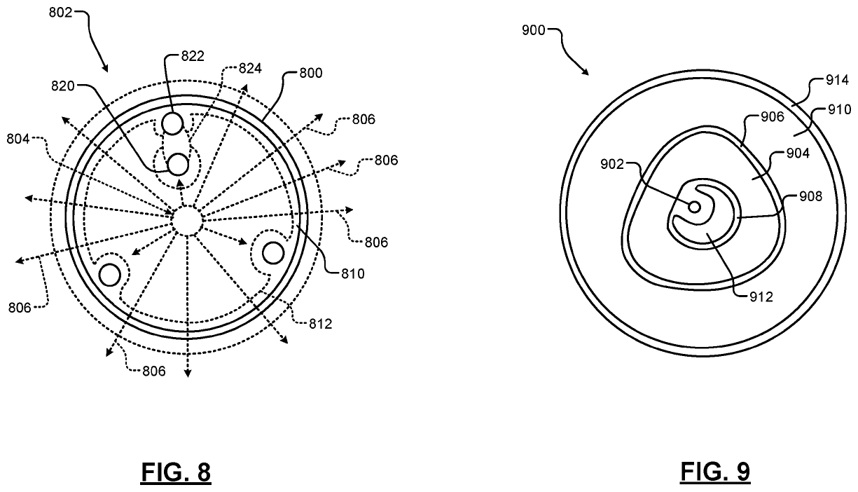

FIG. 9 shows a fluid flow velocity diagram 900 illustrating fluid flow velocities from a showerhead that has a cupped baffle plate and a TMD post, as disclosed herein. The fluid flow velocities may be estimated for example at an area 1 mm above a substrate being processed. The fluid flow velocity diagram 900 includes a region 902 associated with the TMD post, where fluid flow velocities are less than a region 904, which is associated with fluid flow velocities over a lip of the cupped baffle plate. The region 904 experiences the highest fluid flow velocities. Regions 906, 908 experience fluid flow velocities that are less than that of region 904. Regions 910, 912 experience fluid flow velocities that are less than that of regions 906, 908. Region 914 experiences fluid flow velocities that are less than that of regions 910, 912.

FIG. 10 shows a portion 1000 of a cupped baffle plate including a circumferential lip 1002 having a triangular-shaped cross-section. The lip 1002 has a circumferential top edge 1004 and sloped sides 1006, 1008. FIG. 11 shows a portion 1100 of a cupped baffle plate including a circumferential lip 1102 having a hemi-spherically-shaped cross-section. The lip 1102 has a hemi-spherical top surface 1104.

FIG. 12 shows a portion 1200 of a cupped baffle plate including a circumferential lip 1202 having a rounded inner circumferential edge 1204 and a right angled outer circumferential edge 1206. FIG. 13 shows a portion 1300 of a cupped baffle plate including a circumferential lip 1302 with a right angled inner circumferential edge 1304 and a rounded outer circumferential edge 1306.

FIG. 14 shows a portion 1400 of a cupped baffle plate including a circumferential lip 1402 having a ramped cross-section with an outer circumferential edge 1404 having a sloped inner surface 1406. FIG. 15 shows a portion 1500 of a cupped baffle plate including a circumferential lip 1502 having a ramped cross-section with a flat top portion 1504 and a sloped inner surface 1506.

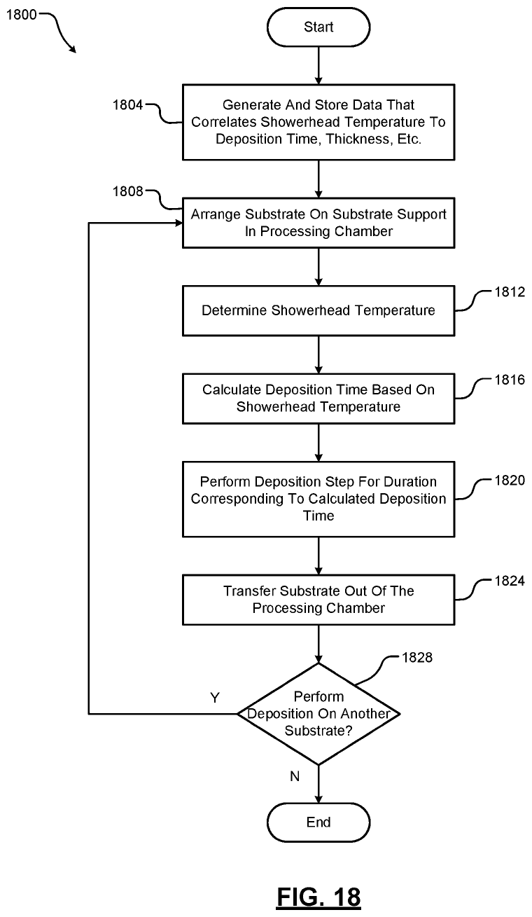

FIG. 16 shows a portion 1600 of a cupped baffle plate including a circumferential lip 1602 having a right angled inner circumferential edge 1604, a flat top surface 1605, and downward sloped outer circumferential surface 1606. FIG. 17 shows a portion 1700 of a cupped baffle plate including a circumferential lip 1702 with a stepped inclining cross-section with a flat top surface 1704 and a stepped inclining surface 1706.

FIGS. 6-7 and 10-17 are provided as examples. Cupped baffle plates may be implemented having lips with cross-sectional shapes that are different than shown in FIGS. 6-7 and 10-17. In FIGS. 6-7, the shown lip has linear side surfaces that are at 90°angles relative to each other. The side surfaces may be at different angles, be curved and/or have different shaped inner and outer edges.

FIG. 18 shows an example method 1800 of operating a substrate processing system including a cupped baffle plate and TMD post as disclosed herein. Other methods may be implemented. The method 1800 may include determining a deposition time. For example, the substrate processing system 300 of FIG. 3, which may include the controller and/or one of the showerheads of FIGS. 3-7 and/or one of the cupped baffle plates of FIGS. 10-17, is configured to perform the method 1800. At 1804, showerhead temperature compensation data is generated and stored. For example, showerhead temperature compensation data is data correlating showerhead temperature to deposition rate, a deposition thickness for a baseline deposition time, etc. as described above. In one example, multiple substrates are processed (e.g., in sequential deposition steps having a same deposition time) while showerhead temperature is monitored. After deposition is complete, respective deposition thicknesses of the substrates are measured. In this manner, respective showerhead temperatures for each deposition thickness (at the same deposition time) can be determined.

At 1808, a substrate is arranged on a substrate support in a processing chamber configured to perform a deposition process on the substrate. At 1812, the controller 400 (e.g., the temperature monitor 440) determines a temperature of a showerhead of the processing chamber. For example, the temperature monitor 440 receives one or more signals from respective sensors (e.g., the TMD 416) configured to sense a temperature of the showerhead.

At 1816, the controller 400 (e.g., the deposition time determiner 442) determines a deposition time based on the showerhead temperature. For example, the deposition time determiner 442 determines the deposition time based on the stored data that correlates showerhead temperature to deposition time and/or thickness as described above. In one example, the stored data is a model or formula configured to determine an adjusted (i.e., optimized) deposition time DT′ based on a baseline deposition time DT and a variable correction factor C according to DT′=DT*C. In some examples, the correction factor is inversely proportional to showerhead temperature. Accordingly, as showerhead temperature increases, the correction factor C decreases (e.g., from a baseline of 1) and the optimized deposition time DT′ decreases. In other examples, the correction factor is directly proportional to showerhead temperature. Accordingly, as showerhead temperature increases, the correction factor C increases and the optimized deposition time DT′ increases.

The correction factor C may be determined based only on the showerhead temperature or based on the showerhead temperature and other inputs such accumulation (i.e., a measured or estimated amount of accumulation of deposition byproducts within the processing chamber), substrate count (i.e., a number of substrates processed in a given sequence or time period affecting showerhead temperature), etc.

At 1820, the controller 400 (e.g., the deposition optimizer 444 performs a deposition step for a duration corresponding to the determined optimized deposition time. For example, the deposition step is performed without pre-heating the showerhead. At 1824, the substrate is transferred out of the processing chamber. At 1828, the controller 400 determines whether to perform deposition on another substrate. If true, the controller 400 continues to 1808. If false, the method 1800 ends.

The examples set forth herein improve wafer-to-wafer (WtW) film thickness consistency across wafers and decrease within wafer (WiW) film thickness non-uniformity percentage. The example cupped baffle plates minimize and/or eliminate fluid flow disturbance caused by a TMD post and standoff elements.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A cupped baffle plate for a showerhead of a substrate processing system, the cupped baffle plate comprising:
a baseplate to be disposed in a plenum of the showerhead to receive a fluid from a stem of the showerhead, the baseplate comprising a plurality of holes to receive a plurality of standoff elements for coupling the baseplate to at least one of a backplate or a faceplate of the showerhead; and
a circumferential lip on the baseplate and adjacent to an outer peripheral edge of the baseplate, the circumferential lip restricting fluid flow over a peripheral edge of the cupped baffle plate.

2. The cupped baffle plate of claim 1, wherein the circumferential lip has a rectangular-shaped cross-section.

3. The cupped baffle plate of claim 1, wherein the circumferential lip comprises a ramped surface.

4. The cupped baffle plate of claim 1, wherein the circumferential lip comprises a rounded upper surface.

5. The cupped baffle plate of claim 1, wherein the circumferential lip comprises:
a first circumferential edge with a rounded cross-section; and
a second circumferential edge with a cross-section having a right angle.

6. The cupped baffle plate of claim 1, wherein the circumferential lip has a stepped surface.

7. The cupped baffle plate of claim 1, wherein the circumferential lip comprises a plurality of ramped surfaces.

8. The cupped baffle plate of claim 1, wherein the circumferential lip comprises a ramped surface and a flat top surface.

9. The cupped baffle plate of claim 1, wherein a width of a cross-section of the circumferential lip is less than a height of the circumferential lip.

10. The cupped baffle plate of claim 1, wherein the cupped baffle plate comprises a post hole to receive a temperature measuring device post.

11. The cupped baffle plate of claim 1, wherein the circumferential lip extends upward from the baseplate and is integrally formed with the baseplate as a unitary component.

12. A showerhead comprising:
the cupped baffle plate of claim 1;
the backplate comprising a fluid supply hole;
the faceplate attached to the backplate, the faceplate in combination with the backplate defining the plenum; and
the stem comprising a fluid channel supplying the fluid to the plenum via the fluid supply hole,
wherein an exit area of the cupped baffle plate is greater than a cross-sectional area of at least one of the fluid supply hole and the fluid channel, the exit area is cylindrical shaped and is equal to a product of i) a distance between the circumferential lip and the backplate, and ii) at least one of an outer circumference of the cupped baffle plate and an uppermost circumferential edge of the circumferential lip.

13. The showerhead of claim 12, wherein a height of the circumferential lip is less than a distance between the backplate and the baseplate.

14. The showerhead of claim 12, further comprising a temperature measuring device post to receive a temperature measuring device, the temperature measuring device post extending through a hole in the cupped baffle plate.

15. The showerhead of claim 14, wherein the temperature measuring device post extends from the faceplate and to the backplate.

16. The showerhead of claim 12, wherein the plurality of standoff elements extend from at least one of the backplate and the faceplate.

17. The showerhead of claim 12, wherein the plurality of standoff elements extend from the backplate and not from the faceplate.

18. The showerhead of claim 12, wherein the exit area of the cupped baffle plate is at least four times the cross-sectional area of the at least one of the fluid supply hole and the fluid channel.

19. A cupped baffle plate for a showerhead of a substrate processing system, the cupped baffle plate comprising:
a baseplate to be disposed in a plenum of the showerhead to receive a fluid from a stem of the showerhead, the baseplate comprising
a plurality of holes to receive a plurality of standoff elements for coupling the baseplate to a backplate of the showerhead, and
a post hole to receive a temperature measuring device post; and
a circumferential lip on the baseplate and adjacent to an out peripheral edge of the baseplate, the circumferential lip in combination with the baseplate reducing turbulence in fluid flow radially outward of the plurality of holes and the post hole and over a peripheral edge of the cupped baffle plate.

20. A showerhead comprising:
the cupped baffle plate of claim 19;
the backplate comprising a fluid supply hole;
a faceplate attached to the backplate, the faceplate in combination with the backplate defining the plenum; and
the stem comprising a fluid channel supplying the fluid to the plenum via the fluid supply hole,
wherein an exit area of the cupped baffle plate is greater than a cross-sectional area of at least one of the fluid supply hole and the fluid channel, the exit area is cylindrical shaped and is equal to a product of i) a distance between the circumferential lip and the backplate, and ii) at least one of an outer circumference of the cupped baffle plate and an uppermost circumferential edge of the circumferential lip.

21. The showerhead of claim 20, wherein:
a width of a cross-section of the circumferential lip is less than a height of the circumferential lip; and
a height of the circumferential lip is less than a distance between the backplate and the baseplate.

22. The showerhead of claim 20, wherein the exit area of the cupped baffle plate is at least four times the cross-sectional area of the at least one of the fluid supply hole and the fluid channel.
